(19) United States
(12) Patent Application Publication
(10) Pub. No.: US 2025/0351295 A1
(43) Pub. Date: Nov. 13, 2025

(54) SPEAKER MODULE

(71) Applicants: AAC ACOUSTIC TECHNOLOGIES (SHENZHEN) CO., LTD., Shenzhen (CN); AAC Microtech (Changzhou) Co., Ltd., Changzhou City (CN)

(72) Inventors: Shuwen Wu, Shenzhen (CN); Zhenfan Ge, Shenzhen (CN)

(21) Appl. No.: 17/921,975

(22) PCT Filed: Apr. 20, 2022
(86) PCT No.: PCT/CN2022/087962

§ 371 Date: Mar. 11, 2025

(30) Foreign Application Priority Data
Apr. 7, 2022 (CN) 202210361094.X

(51) Int. Cl. H05K 7/20; H04R 1/02

(52) U.S. Cl. CPC H05K 7/20263; H04R 1/025; H05K 7/20272

(57) ABSTRACT

The present application provides a speaker module, including a casing, a speaker driver arranged in an accommodating cavity of the casing, a heat dissipation bracket, and a heat dissipation pipe arranged on the heat dissipation bracket outside the casing and abutted against the heat dissipation members outside the speaker module. The heat dissipation bracket is provided with a first cooling channel, which is arranged around the speaker driver. The heat dissipation pipe is provided with a second cooling channel communicated with the first cooling channel. Both the first cooling channel and the second cooling channel are filled with cooling liquid. The heat generated by the vibration of the speaker driver can be transferred to the outside through the cooling liquid in the first and so that the circulating flow of the cooling liquid is realized, and the heat dissipation efficiency of the heat dissipation bracket is improved.

### TECHNICAL FIELD

The present application relates to the technical field of speakers, in particular to a speaker module.

### BACKGROUND

A speaker module in the prior art includes a speaker driver arranged in an accommodating cavity and a heat dissipation bracket arranged around the speaker driver. When the speaker driver vibrates during operation, the heat generated by the speaker driver is transferred to the accommodating cavity through the heat dissipation bracket.

### SUMMARY OF THE INVENTION

### Technical Problem

However, it leads to poor heat dissipation efficiency of the speaker module by this heat dissipation method, and there is a risk of damage to the speaker driver due to a high temperature in the accommodating cavity.

Therefore, it is necessary to provide a speaker module with high heat dissipation efficiency.

### SOLUTION TO THE PROBLEM

### Technical Problem

An object of the present application is to provide a speaker module with high heat dissipation efficiency.

The technical solutions of the present application are as follows: a speaker module, comprising:
a casing provided with an accommodating cavity;
a speaker driver arranged in the accommodating cavity;
a heat dissipation bracket provided with a first cooling channel arranged around the speaker driver; and
a heat dissipation pipe, arranged on the heat dissipation bracket, located outside the casing and abutted against a heat dissipation member outside the speaker module, and provided with a second cooling channel communicated with the first cooling channel;
wherein the first cooling channel and the second cooling channel are filled with cooling liquid.

In one possible design, the heat dissipation bracket comprises a body portion, wherein a part of the body portion is arranged in the accommodation cavity, and the other part of the body portion is arranged on an outer side of the casing; one end of the body portion located on the outer side of the casing is provided with an extension portion that is bent and extended upward along a thickness direction of the speaker module;
a part of the first cooling channel is provided in the body portion, and the other part of the first cooling channel is provided in the extension portion.

In one possible design, the first cooling channel comprises a first channel, a second channel, a third channel, a fourth channel and a fifth channel; wherein the first channel, the second channel and the third channel are provided on the body portion, and the fourth channel and the fifth channel are provided on the extension portion;
the first channel and the second channel are arranged oppositely along a first direction; the third channel is extended along the first direction and capable of communicating with the first channel and the second channel; the fourth channel is extended along a third direction and capable of communicating with the second cooling channel and the second channel, and the fifth channel is capable of communicating with the second cooling channel and the first channel;
the first direction is perpendicular to the third direction.

In one possible design, an inner diameter of the fifth channel is smaller than an inner diameter of the fourth channel, and an inner diameter of the second cooling channel is greater than or equal to an inner diameter of the fourth channel.

In one possible design, one end of the first channel is provided with a first bent channel extended toward the second channel along the first direction, and a second bent channel extended along a second direction and capable of communicating with the first bent channel and the fifth channel;
one end of the second channel is provided with a third bent channel extended toward the first channel along the first direction, and a fourth bent channel extended along the second direction and capable of communicating with the third bent channel and the fourth channel;
the second direction is perpendicular to both the first direction and the third direction.

In one possible design, the heat dissipation bracket is provided with a first through hole arranged through a side wall of the heat dissipation bracket along the second direction, and the fourth channel and the fifth channel are respectively arranged on opposite sides of the first through hole along the first direction.

In one possible design, the heat dissipation bracket comprises an upper bracket and a lower bracket stacked along the third direction, and the extension portion is arranged at one end of the upper bracket outside the casing.

In one possible design, the upper bracket is provided with a first surface contacted with the lower bracket, and the lower bracket is provided with a second surface contacted with the first surface; the first surface is provided with a first groove channel, and the second surface is provided with a second groove channel;
after the upper bracket and the lower bracket are connected, the first groove channel and the second groove channel enclose to form the first channel, the second channel and the third channel.

In one possible design, the second cooling channel comprises a sixth channel coaxially arranged with the fourth channel, a seventh channel coaxially arranged with the fifth channel, and an eighth channel extended along the first direction and capable of communicating with the sixth channel and the seventh channel;

In one possible design, opposite ends of the heat dissipation pipe along the first direction are respectively provided with a first bent section and a second bent section that are bent and extended toward the extension portion; the sixth channel is arranged in the first bent section, and the seventh channel is arranged in the second bent section.

It should be understood that the above general description and the following detailed description are merely exemplary and do not limit the present application.

### BENEFICIAL EFFECT OF THE INVENTION

### Beneficial Effect

The present application has the following beneficial effects. An interior of the heat dissipation bracket is provided with a first cooling channel configured to accommodate the cooling liquid and arranged around the speaker driver and, and an interior of the heat dissipation pipe is provided with a second cooling channel configured to accommodate the cooling liquid and abutted against the heat dissipation members outside the speaker module. Therefore, the heat generated by the vibration of the speaker driver can be transferred to the heat dissipation bracket, and then transferred to the outside through the cooling liquid in the first cooling channel and the second cooling channel, and the high-temperature cooling liquid in the first cooling channel flows from the second cooling channel under the action of the pressure difference, so as to realize the circulating flow of the cooling liquid, thereby improving the heat dissipation efficiency of the heat dissipation bracket.

### BRIEF DESCRIPTION OF THE DRAWINGS

### Description of the Drawings

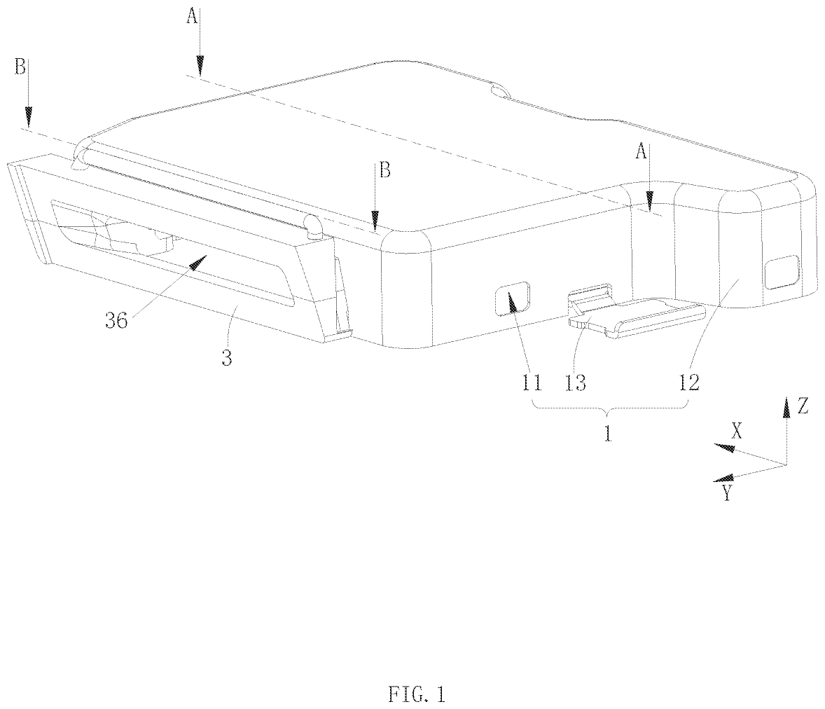

FIG. 1 is a partial structural view of a speaker module according to an embodiment of present application.

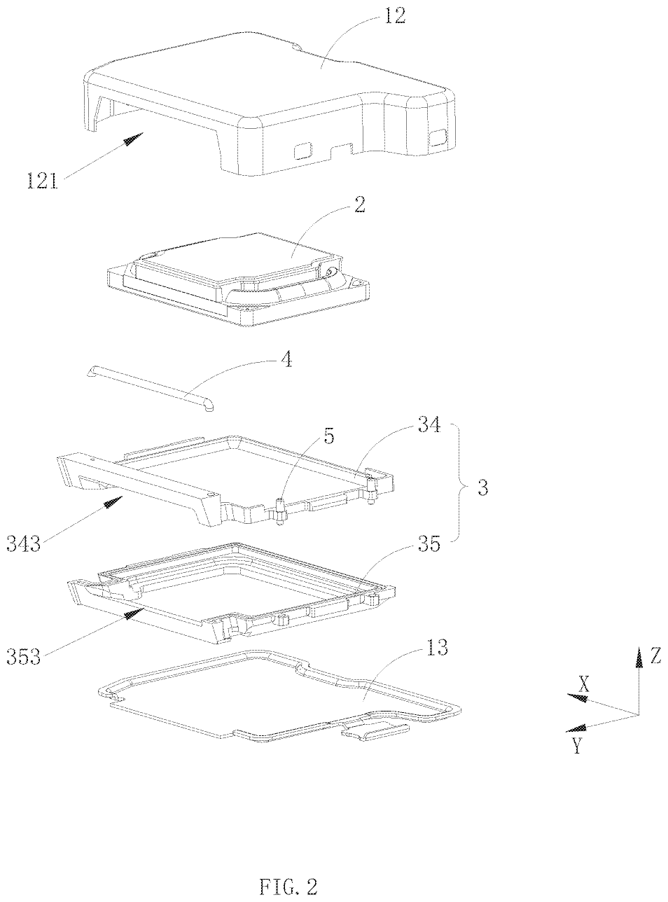

FIG. 2 is an exploded view of the speaker module in FIG. 1.

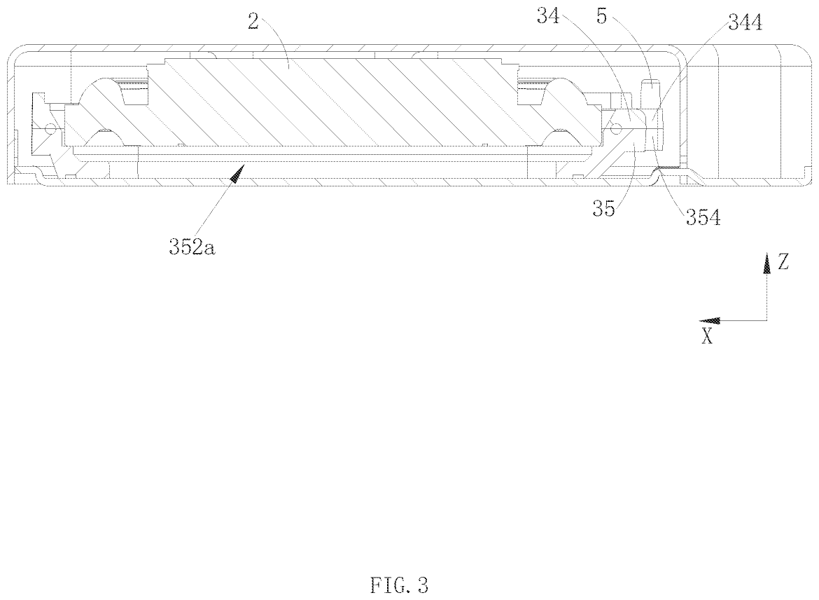

FIG. 3 is a sectional view taken along a line A-A in FIG. 1.

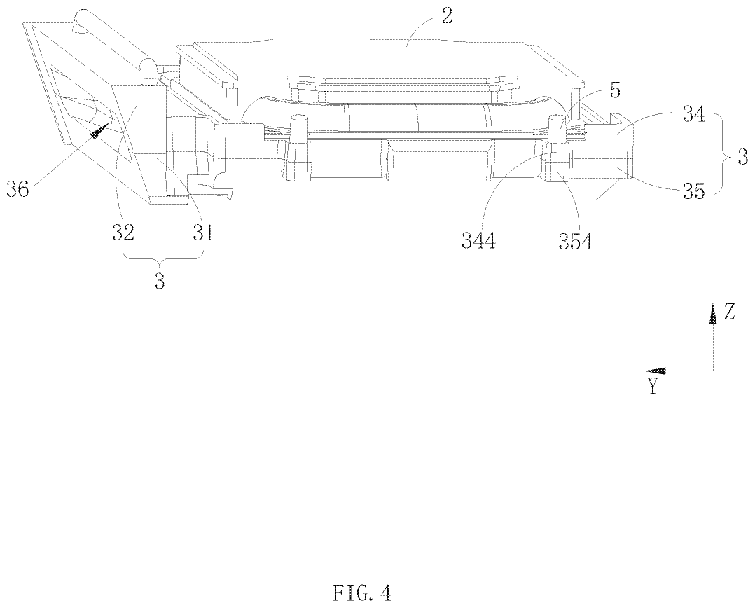

FIG. 4 is a schematic view of the speaker module with a casing removed in FIG. 1.

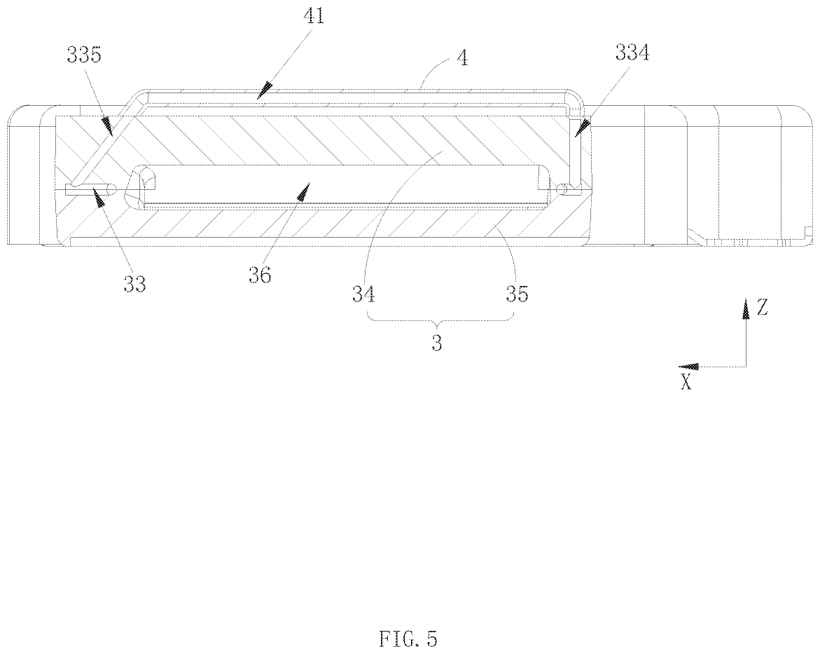

FIG. 5 is a sectional view taken along a line B-B in FIG. 1.

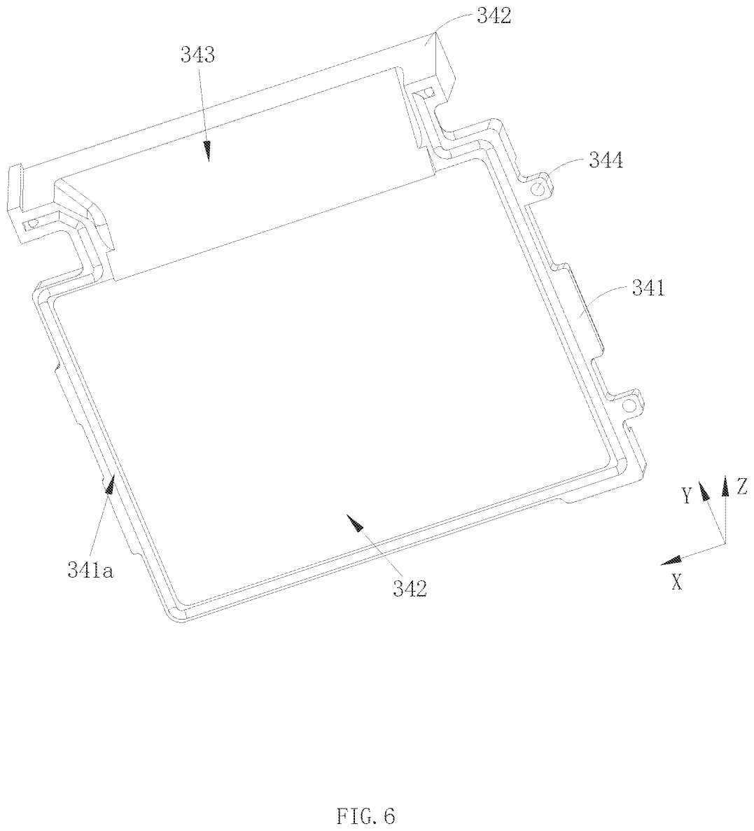

FIG. 6 is a bottom view of an upper bracket in FIG. 2.

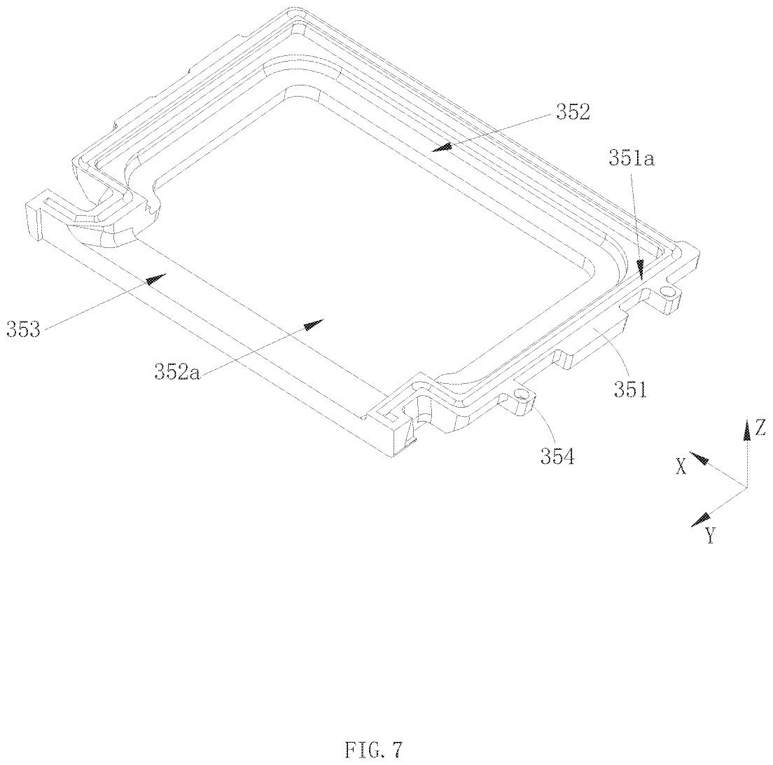

FIG. 7 is a top view of a lower bracket in FIG. 2.

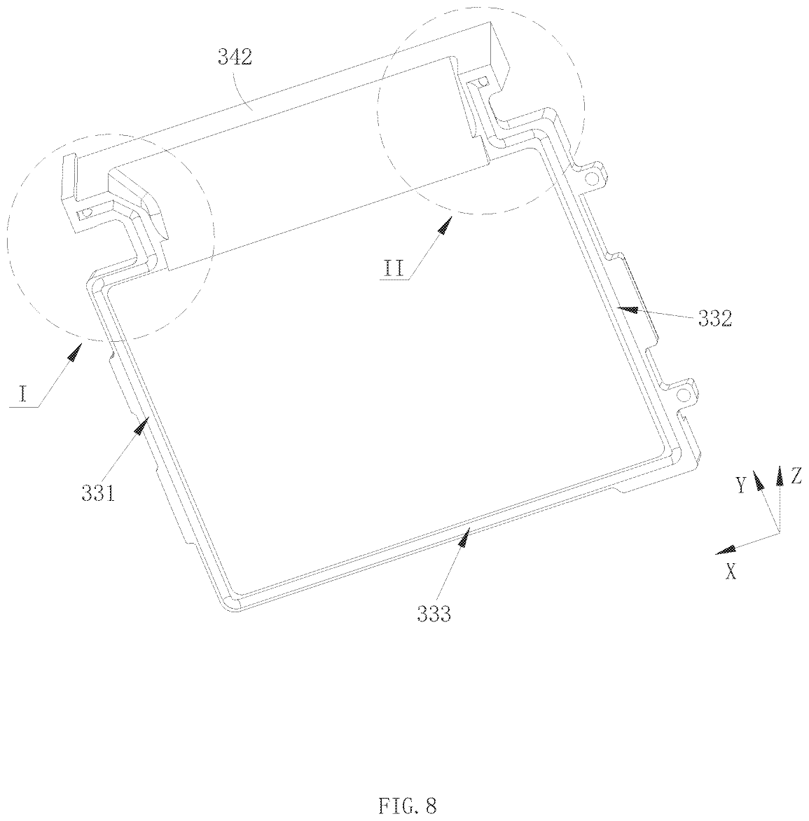

FIG. 8 is a schematic view of a first cooling channel in the speaker module according to an embodiment of present application.

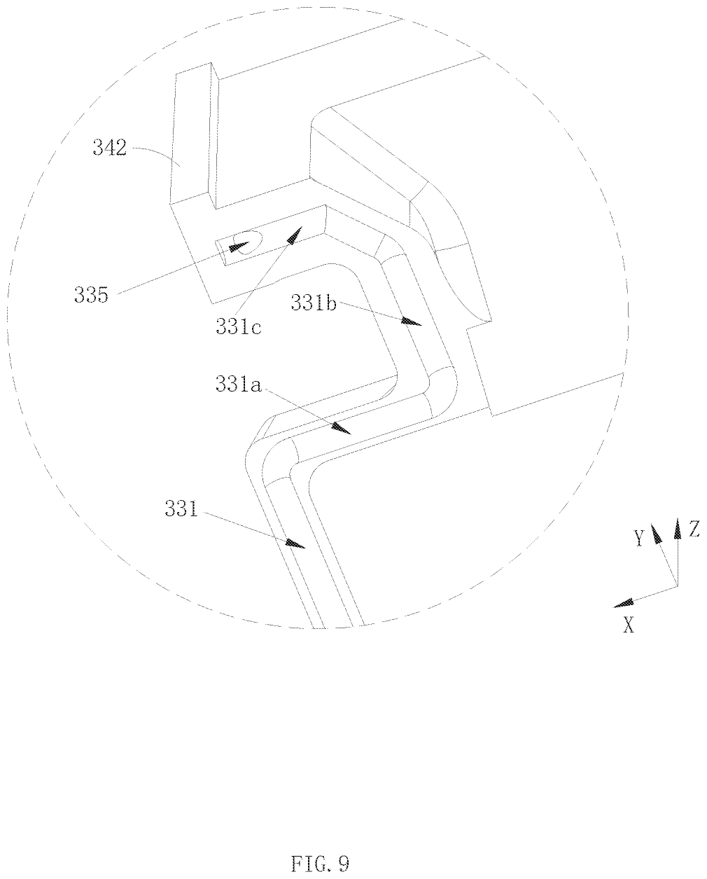

FIG. 9 is an enlarged view of part I in FIG. 8.

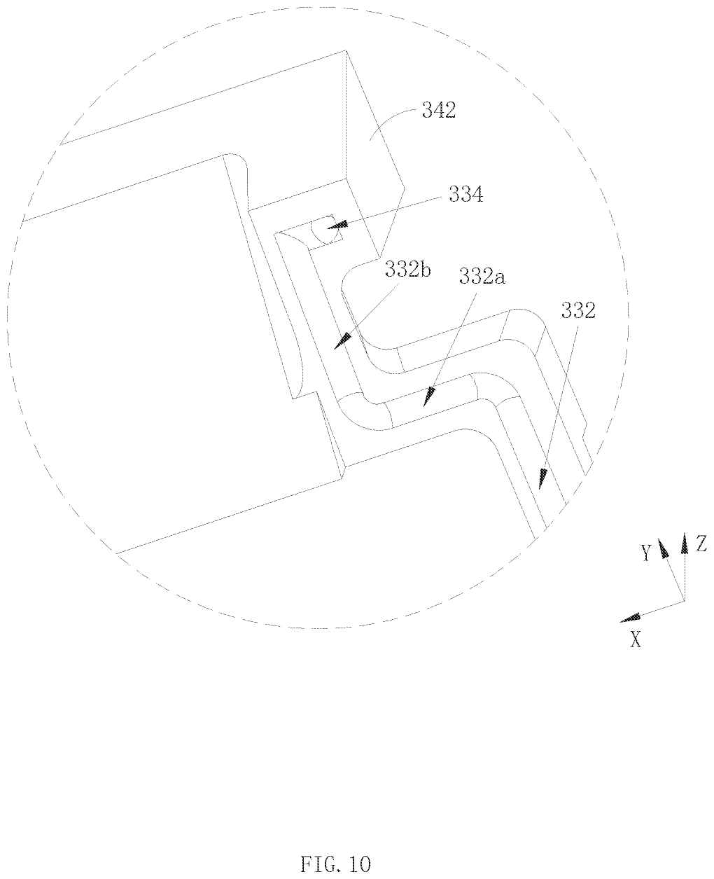

FIG. 10 is an enlarged view of part II in FIG. 8.

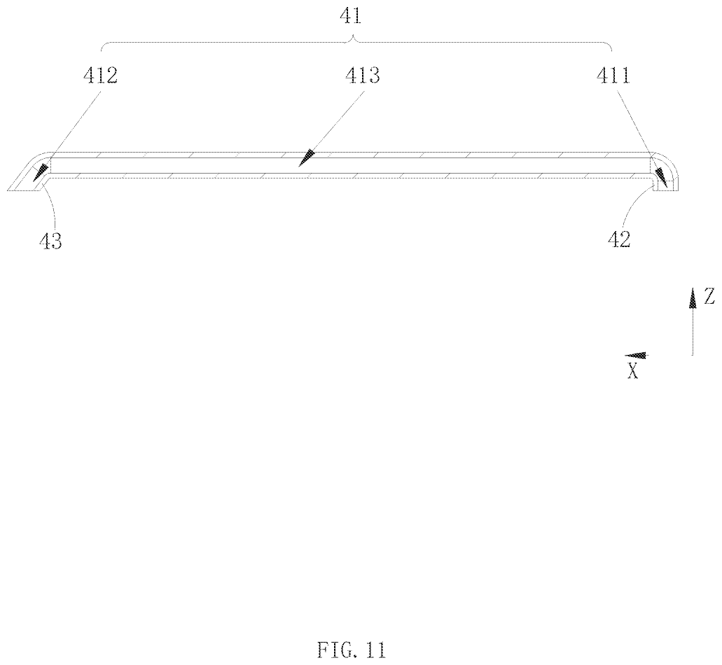

FIG. 11 is a sectional view of a heat dissipation pipe in FIG. 1 taken along the line B-B.

### REFERENCE NUMBERS

1—Casing;
   11—Accommodating cavity;
   12—Upper cover;
      121—First opening;
   13—Base;
2—Speaker driver;
3—Heat dissipation bracket;
   31—Body portion;
   32—Extension portion;
   33—First cooling channel;
      331—First channel;
         331a—First bent channel;
         331b—Second bent channel;
         331c—Fifth bent channel;
      332—Second channel;
         332a—Third bent channel;
         332b—Fourth bent channel;
      333—Third channel;
      334—Fourth channel;
      335—Fifth channel;
   34—Upper bracket;
      341—First surface;
         341a—First groove channel;
      342—Mounting hole;
      343—Second opening;
      344—Mounting portion;
   35—Lower bracket;
      351—Second surface;
         351a—Second groove channel;
      352—Mounting groove;
         352a—Second through hole;
      353—Third opening;
      354—Mounting matching portion;
   36—First through hole;
4—Heat dissipation pipe;
   41—Second cooling channel;
      411—Sixth channel;
      412—Seventh channel;
      413—Eighth channel;
         42—First bent section;
         43—Second bent section;
5—Connecting member.

The accompanying drawings herein, which are incorporated into and form a part of the specification, illustrate embodiments consistent with the present application and are used in conjunction with the specification to explain the principles of the present application.

### BEST EMBODIMENTS FOR PRACTICING THE INVENTION

### Best Embodiments for the Invention

In order to better understand the technical solutions of the present application, embodiments of the present application are described in detail below in conjunction with the accompanying drawings.

It should be clear that the described embodiments are only some of the embodiments of the present application. Based on the embodiments in the application, all other embodiments obtained by a person of ordinary skill in the art without creative labor are within the scope of protection of this application.

The present application provides a speaker module arranged in terminal devices (including but not limited to mobile phones and computers). A specific structure of the speaker module is shown in FIG. 1 and FIG. 2. The speaker driver 2 includes a casing 1, a speaker driver 2 arranged inside an accommodating cavity 11 of the casing 1, a heat dissipation bracket 3 arranged around the speaker unit 2 and a heat dissipation pipe 4 arranged on the heat dissipation bracket 3 and abutted against heat dissipation members outside the speaker module. The heat dissipation bracket 3 and the heat dissipation pipe 4 are made of metals with good thermal conductivity, including but not limited to copper, and copper alloy. The heat dissipation members include but are not limited to a middle frame and a casing of the terminal devices. A material of the heat dissipation members is metal or other material with good thermal conductivity. For ease of understanding, as shown in FIG. 1, the speaker module provided by the present application has a first direction X, a second direction Y and a third direction Z. The first direction X is perpendicular to the second direction Y. The first direction X is perpendicular to the third direction Z, and the second direction Y is perpendicular to the third direction Z.

As shown in FIG. 1 and FIG. 2, the casing 1 includes an upper cover 12 and a base 13 that are arranged opposite to each other along the second direction Y and are configured to enclose the accommodating cavity 11. The upper cover 12 is provided with a first opening 121. When the upper cover 12 and the base13 are connected, a part of the heat dissipation bracket 3 can be extended out of the casing 1 through the first opening 121. The upper cover 12 and the base 13 are integrally formed or detachably connected. When the upper cover 12 and the base 13 are integrally formed, the structural stability of the casing 1 can be increased. When the upper cover 12 and the base 13 are detachably connected, the mounting, maintenance and replacement of internal members of the accommodating cavity 11 can be facilitated. In the present application, the connection method between the upper cover 12 and the base 13 are not specifically limited.

As shown in FIG. 1 and FIG. 2, the heat dissipation bracket 3 includes a body portion 31. A part of the body portion 31 is arranged in the accommodating cavity 11, and the other part of the body portion 31 is extended to an outer side of the casing 1. One end of the body portion 31 on the outer side of the casing 1 is provided with an extension portion 32 that is bent and extended upward along a thickness direction of the speaker module (i.e., along the third direction Z). In addition, the heat dissipation bracket 3 is provided with a first cooling channel 33. The first cooling channel 33 is arranged around the speaker driver 2. The heat dissipation pipe 4 is provided with a second cooling channel 41 communicated with the first cooling channel 33. The second cooling channel 41 is extended away from the speaker driver 2 along the third direction Z.

In this embodiment, an interior of the heat dissipation bracket 3 is provided with a first cooling channel 33 arranged through the speaker driver 2 and configured to accommodate the cooling liquid, and an interior of the heat dissipation pipe 4 is provided with a second cooling channel 41 abutted against the heat dissipation members and configured to accommodate the cooling liquid. The heat generated by the vibration of the speaker driver 2 can be transferred to the heat dissipation bracket 3, and then transferred to the outside air and the metal heat dissipation members through the cooling liquid in the first cooling channel 33 and the second cooling channel 41, so as to reduce the temperature of the speaker driver 2. Besides, the heat dissipation pipe 4 is located outside the accommodating cavity 11 and is abutted against the heat dissipation members, so that the temperature of the cooling liquid in the second cooling channel 41 is lower than the temperature of the cooling liquid in the first cooling channel 33, and the pressure in the second cooling channel 41 is lower than the pressure in the first cooling channel 33. Therefore, the high-temperature cooling liquid in the first cooling channel 33 flows into the second cooling channel 41 under an action of the pressure difference, thereby realizing the circulating flow of the cooling liquid, and further improving the heat dissipation bracket 3 cooling efficiency.

The heat dissipation pipe 4 is fixedly or detachably connected to the heat dissipation bracket 3. When the heat dissipation pipe 4 is fixedly connected to the heat dissipation bracket 3, the stability of the connection between the heat dissipation pipe 4 and the heat dissipation bracket 3 can be improved, and a risk of cooling liquid leakage caused by a separation of the heat dissipation pipe 4 and the heat dissipation bracket 3 during a working process of the speaker module is reduced, which is beneficial to improve the working stability of the heat dissipation pipe 4 and the heat dissipation bracket 3. When the heat dissipation pipe 4 and the heat dissipation bracket 3 are detachably connected, a size of the heat dissipation pipe 4 may be adjusted according to the practical size and use requirements during the mounting process, so that the heat dissipation pipe 4 can be attached to the heat dissipation members with different heights, thereby increasing the application range of the heat dissipation bracket 3 and the heat dissipation pipe 4.

Specifically, as shown in FIG. 2 and FIG. 3, the heat dissipation bracket 3 includes an upper bracket 34 and a lower bracket 35 that are stacked along the third direction Z. The upper bracket 34 and the lower bracket 35 are detachably connected or fixedly connected. As shown in FIG. 3 and FIG. 4, the upper bracket 34 is provided with a mounting portion 344. The lower bracket 35 is provided with a mounting matching portion 354. The mounting portion 344 and the mounting matching portion 354 are connected by connecting members 5, so as to realize a detachable connection between the upper bracket 34 and the lower bracket 35, and facilitate the mounting and removal of the mounting bracket. The types of the connecting member 5 include, but are not limited to, screws, screw rods and positioning posts.

More specifically, as shown in FIG. 4, the heat dissipation bracket 3 includes a body portion 31 and an extension portion 32. After the upper bracket 34 and the lower bracket 35 are connected, along the third direction Z, the upper bracket 34 and the lower bracket 35 are joined together to form the heat dissipation bracket 3. The body portion 31 of the upper bracket 34 is bent and extended upward along the third direction Z to form the extension portion 32 of the heat dissipation bracket 3.

As shown in FIG. 5, the heat dissipation bracket 3 is provided with a first through hole 36, and at least part of the first through hole 36 is located in a space enclosed by the second cooling channel 41, so as to increase a contact area between the second cooling channel 41 and the air, thereby further improving the heat dissipation efficiency of the heat dissipation bracket 3. Besides, the materials required for processing the heat dissipation bracket 3 can be reduced while ensuring the structural strength of the heat dissipation support 3, thereby reducing the processing cost of the heat dissipation bracket 3, and reduce the weight of the heat dissipation bracket 3.

Specifically, as shown in FIGS. 6 and 7, the upper bracket 34 is provided with a second opening 343. The lower bracket 35 is provided with a third opening 353. After the upper bracket 34 and the lower bracket 35 are connected, the second opening 343 and the third opening 353 enclose the first through hole 36, so as to simplify the structures of the upper bracket 34 and the lower bracket 35, thereby reducing the production cost of the heat dissipation bracket 3.

As shown in FIG. 6 and FIG. 7, the upper bracket 34 is provided with a mounting hole 342 arranged through the upper bracket 34 along the third direction Z. The lower bracket 35 is provided with a mounting groove 352. The mounting hole 342 is arranged opposite to the mounting groove 352, and a part of the speaker driver 2 is extended into the mounting hole 342 and abutted against a bottom wall of the mounting groove 352, so as to simplify the connection between the speaker driver 2 and the heat dissipation bracket 3, and further simplify the structure of the speaker driver 2 and the heat dissipation bracket 3. The connection method of the speaker driver 2 and the bottom wall of the mounting groove 352 includes but is not limited to bonding and welding. In addition, as shown in FIG. 7, the bottom wall of the mounting groove 352 is provided with a second through hole 352a, and a part of the speaker driver 2 is exposed in the accommodating cavity 11 through the second through hole 352a, thereby increasing the contact area between the speaker driver 2 and the air. If the heat dissipation bracket 3 fails to work normally, the speaker driver 2 can also dissipate heat through the air in the accommodating cavity 11, which increases the heat dissipation path of the speaker driver 2, and further increases heat dissipation efficiency and heat dissipation stability of the speaker module.

In addition, as shown in FIG. 6 and FIG. 7, the upper bracket 34 is provided with a first surface 341. The lower bracket 35 is provided with a second surface 351. After the upper bracket 34 and the lower bracket 35 are connected, the first surface 341 and the second surface 351 are abutted against each other. The first surface 341 is provided with a first channel 341a, and the second surface 351 is provided with a second channel 351a. After the upper bracket 34 and the lower bracket 35 are connected, the first channel 341a and the second channel 351a enclose a part of the first cooling channel 33, so as to facilitate the processing of the first cooling channel 33, thereby reducing the process required for processing the heat dissipation bracket 33, and further reducing the processing cost of the heat dissipation bracket 33. As shown in FIG. 5, the other part of the first cooling channel 33 is arranged in the extension portion 32. Since the extension portion 32 is arranged outside the casing 1, the contact area between the first cooling channel 33 and the air is increased, thereby improving the heat dissipation efficiency of the heat dissipation bracket.

As shown in FIGS. 8-10, the first cooling channel 33 includes a first channel 331 and a second channel 332 that are oppositely arranged along the first direction X, a third channel 333 extended along the first direction X and capable of communicating with the first channel 331 and the second channel, a fourth channel 334 and a fifth channel 335 extended along the third direction Z. The first channel 331, the second channel 332 and the third channel 333 are all arranged on the body portion 31 of the heat dissipation bracket 3. The first channel 331, the second channel 332 and the third channel 333 arranged around the speaker driver 22. The fourth channel 334 and the fifth channel 335 are both arranged on the extension portion 32 of the heat dissipation bracket 3. As shown in FIG. 11, the second cooling channel 41 includes a sixth channel 411 coaxially arranged with the fourth channel 334, a seventh channel 412 arranged coaxially with the fifth channel 335, and an eighth channel 413 extended along the first direction X and capable of communicating with the sixth channel 411 and the seventh channel 412. The sixth channel 411 is communicated with the fourth channel 334, and the seventh channel 412 is communicated with the fifth channel 335, so as to realize a communication between the first cooling channel 33 and the second cooling channel 41. An inner diameter of the fifth channel 335 is smaller than an inner diameter of the fourth channel 334, so that the pressure in the fifth channel 335 is higher than the pressure in the fourth channel 334, and the cooling liquid has a preset flow trajectory, that is, the first channel 331—the fifth channel 335—the seventh channel 412—the eighth channel 413—the sixth channel 411—the fourth channel 334—the second channel 332—the third channel 333—the first channel 331, Therefore, the cooling liquid has a stable flow trajectory in the heat dissipation bracket 3, so that a risk of blocking the first cooling channel 33 or the second cooling channel 41 due to the opposite flow direction of the cooling liquid is reduced, thereby improving the stability of the cooling liquid flow, and improving the working stability of the heat dissipation bracket 3.

Specifically, as shown in FIGS. 8-10, one end of the first channel 331 is provided with a first bent channel 331a extended toward the second channel 332 along the first direction X, and one end of the second channel 332 is provided with a third bent channel 332a extended toward the first channel 331 along the first direction X, so as to increase the contact area between the first cooling channel 33 and the speaker driver 2, and further improve the heat dissipation efficiency of the heat dissipation bracket 3. The first channel 331 is further provided with a second bent channel 331b bent and extended along the second direction Y and a fifth bent channel 331c bent and extended away from the second channel 332 along the first direction X. The first bent channel 331a and the fifth channel 335 are communicated with each other through the second bent channel 331b and the fifth bent channel 331c. The second channel 332 is further provided with a third bent channel 332a bent and extended along the second direction Y and capable of communicating with the third bent channel 332a, and a fourth bent channel 332b capable of communicating with the fourth channels 334, so as to facilitate the communication between the fourth channel 334 and the second channel 332, thereby simplifying the structure of the first cooling channel 33, and further reducing the processing cost of the first cooling channel 33.

More specifically, as shown in FIG. 11, opposite ends of the heat dissipation pipe 4 along the first direction X are respectively provided with a first bent section 42 and a second bent section 43 that are bent and extended toward the extension portion 32. The sixth channel 411 is arranged on the first bent section 42, and the seventh channel 412 is arranged on the second bent section 43. When the heat dissipation pipe 4 is arranged on the heat dissipation bracket 3, due to the existence of the first bent section 42 and the second bent section 43, there is a gap of a preset size between the heat dissipation pipe 4 and the heat dissipation bracket 3, thereby increasing the contact area between the second cooling channel 41 and the air, further increasing the heat dissipation efficiency of the second cooling channel 41, and further improving the heat dissipation effect of the speaker module.

In addition, the heat dissipation bracket 3 is provided with a liquid injection port. The first cooling channel 33 and the second cooling channel 41 can be communicated with the outside through the liquid injection port, so as to inject cooling liquid into the first cooling channel 33 and the second cooling channel 41. In the present application, the specific position, shape and size of the liquid injection port are not particularly limited. In the present application, the liquid injection port is arranged at a top end of the extension portion 32 along the third direction Z and is communicated with the fourth channel 334.

It should be noted that portions of this patent application document contain copyrighted content. The copyright holder retains the copyright except for making copies of the contents of patent documents or recorded patent files at the Patent Office.

What is claimed is:

1. A speaker module, comprising:
a casing provided with an accommodating cavity;
a speaker driver arranged in the accommodating cavity;
a heat dissipation bracket provided with a first cooling channel arranged around the speaker driver; and
a heat dissipation pipe, arranged on the heat dissipation bracket, located outside the casing and abutted against a heat dissipation member outside the speaker module, and provided with a second cooling channel communicated with the first cooling channel;
wherein the first cooling channel and the second cooling channel are filled with cooling liquid.

2. The speaker module of claim 1, wherein the heat dissipation bracket comprises a body portion, wherein a part of the body portion is arranged in the accommodation cavity, and the other part of the body portion is arranged on an outer side of the casing; one end of the body portion located on the outer side of the casing is provided with an extension portion that is bent and extended upward along a thickness direction of the speaker module;
a part of the first cooling channel is provided in the body portion, and the other part of the first cooling channel is provided in the extension portion.

3. The speaker module of claim 2, wherein the first cooling channel comprises a first channel, a second channel, a third channel, a fourth channel and a fifth channel;
wherein the first channel, the second channel and the third channel are provided on the body portion, and the fourth channel and the fifth channel are provided on the extension portion;
the first channel and the second channel are arranged oppositely along a first direction; the third channel is extended along the first direction and capable of communicating with the first channel and the second channel; the fourth channel is extended along a third direction and capable of communicating with the second cooling channel and the second channel, and the fifth channel is capable of communicating with the second cooling channel and the first channel;
the first direction is perpendicular to the third direction.

4. The speaker module of claim 3, wherein an inner diameter of the fifth channel is smaller than an inner diameter of the fourth channel, and an inner diameter of the second cooling channel is greater than or equal to an inner diameter of the fourth channel.

5. The speaker module of claim 3, wherein one end of the first channel is provided with a first bent channel extended toward the second channel along the first direction, and a second bent channel extended along a second direction and capable of communicating with the first bent channel and the fifth channel;
one end of the second channel is provided with a third bent channel extended toward the first channel along the first direction, and a fourth bent channel extended along the second direction and capable of communicating with the third bent channel and the fourth channel;
the second direction is perpendicular to both the first direction and the third direction.

6. The speaker module of claim 3, wherein the heat dissipation bracket is provided with a first through hole arranged through a side wall of the heat dissipation bracket along the second direction, and the fourth channel and the fifth channel are respectively arranged on opposite sides of the first through hole along the first direction.

7. The speaker module of claim 3, wherein the heat dissipation bracket comprises an upper bracket and a lower bracket stacked along the third direction, and the extension portion is arranged at one end of the upper bracket outside the casing.

8. The speaker module of claim 7, wherein the upper bracket is provided with a first surface contacted with the lower bracket, and the lower bracket is provided with a second surface contacted with the first surface; the first surface is provided with a first groove channel, and the second surface is provided with a second groove channel;
after the upper bracket and the lower bracket are connected, the first groove channel and the second groove channel enclose to form the first channel, the second channel and the third channel.

9. The speaker module of claim 3, wherein the second cooling channel comprises a sixth channel coaxially arranged with the fourth channel, a seventh channel coaxially arranged with the fifth channel, and an eighth channel extended along the first direction and capable of communicating with the sixth channel and the seventh channel;

10. The speaker module of claim 9, wherein opposite ends of the heat dissipation pipe along the first direction are respectively provided with a first bent section and a second bent section that are bent and extended toward the extension portion; the sixth channel is arranged in the first bent section, and the seventh channel is arranged in the second bent section.
